(19) United States
(12) Patent Application Publication
(10) Pub. No.: US 2025/0391702 A1
(43) Pub. Date: Dec. 25, 2025

(54) METHOD FOR OXIDISING A SILICON LAYER

(71) Applicant: COMMISSARIAT A L'ENERGIE ATOMIQUE ET AUX ENERGIES ALTERNATIVES, PARIS (FR)

(72) Inventors: Frédéric MILESI, GRENOBLE CEDEX 09 (FR); Frédéric MAZEN, GRENOBLE CEDEX 09 (FR); Laurent LACHAL, GRENOBLE CEDEX 09 (FR); Sébastien KERDILES, GRENOBLE CEDEX 09 (FR)

(21) Appl. No.: 19/244,675

(22) Filed: Jun. 20, 2025

(30) Foreign Application Priority Data
Jun. 21, 2024 (FR) FR2406727

(51) Int. Cl. H01L 21/762; H01L 21/02

(52) U.S. Cl. CPC H01L 21/76213; H01L 21/02238; H01L 21/02299

(57) ABSTRACT

A method for oxidising a silicon layer includes providing a substrate including a silicon layer; implanting at least once sulphur atoms in at least one zone of the silicon layer; wet oxidising said silicon layer implanted.

### CROSS-REFERENCE TO RELATED APPLICATIONS

This application claims priority to French Patent Application No. 2406727, filed Jun. 21, 2024, the entire content of which is incorporated herein by reference in its entirety.

### FIELD

This invention generally relates to the field of microelectronics. It relates more particularly to a method for oxidising a silicon layer.

### BACKGROUND

Oxidation is a very important step in making silicon integrated circuits. It is used for different applications, especially for creating isolation zones between different components of an integrated structure.

It is therefore appropriate to have an expert knowledge of the oxidation methods.

Different techniques are known for obtaining silicon oxide, such as, for example, thermal oxidation in the presence of oxygen, known as dry oxidation, or thermal oxidation in the presence of water vapour, known as wet oxidation.

Thermal oxidation involves exposing silicon to high temperatures (generally between 800° C. and 1200° C.) in the presence of oxygen (dry phase) or water vapour (wet phase). Oxygen reacts with silicon to form silicon oxide SiO2 on the surface.

It can be interesting to try to modulate the oxidation rate of silicon either by slowing it down or, more conventionally, by increasing it so as to obtain a given oxide thickness more quickly. Methods for modulating the thermal oxidation rate of silicon are known. Thus, doping silicon with elements such as phosphorus or boron speeds up the oxidation rate and gives an oxidation ratio between 0.5 and 2: by oxidation ratio, it is meant the ratio of the oxide thickness obtained with doping to the oxide thickness obtained under the same operating conditions without doping.

### SUMMARY

An aspect of the invention is directed to accelerating the thermal oxidation rate of silicon by providing a method that especially enables oxidation ratios well in excess of 2 to be achieved while retaining good quality of the layer oxidised.

An aspect of the invention thereby relates to a method for oxidising a silicon layer including the following steps of:
implanting sulphur atoms in at least one zone of the silicon layer;
wet oxidising said silicon layer implanted.

By wet oxidation, it is meant an oxidation step performed in the presence of water vapour at a temperature higher than room temperature, such as in an embodiment above 700° C. This wet oxidation can take place either in the presence of water vapour alone or in a mixed atmosphere including both water vapour and dioxygen or water vapour and hydrogen chloride gas.

Particularly surprisingly, the inventors realised that the combination of doping silicon with sulphur atoms and using wet oxidation made it possible to obtain a significant acceleration in oxidation compared with known techniques and to obtain oxidation ratios well in excess of 2. To achieve this, it is appropriate for the oxidation to take place under an atmosphere of water vapour (i.e. a dry atmosphere does not give the same results) and for the sulphur atoms to be implanted into silicon. It is therefore essential to make a sulphur-implanted zone, referred to hereafter as a box, directly in silicon.

Further to the characteristics just discussed in the preceding paragraphs, the oxidation method according to one or more embodiments of the invention may have one or more additional characteristics from among the following, considered individually or according to any technically possible combinations:
the step of implanting sulphur atoms is performed in such a way as to obtain a sulphur concentration in the implanted zone that is strictly lower than 5·10²¹ at/cm³ and in an embodiment strictly lower than 3·10²¹ at/cm³.
the substrate comprising a silicon layer further includes an oxide layer on the silicon layer, implanting then being performed so that the sulphur atoms are implanted under the oxide layer.
wet oxidising is performed:
   in the presence of water vapour or
   under an atmosphere that includes both water vapour and dioxygen, or
   under an atmosphere including water vapour and hydrogen gas.
wet oxidising is performed at a temperature strictly greater than 700° C.
implanting sulphur atoms is performed to a thickness greater than or equal to 10 nm.
the method includes a plurality of successively made implantation steps having different implantation doses and/or acceleration voltages so as to achieve a uniform sulphur concentration over a given thickness.
The method according to a first embodiment includes:
   a step of masking at least one zone of the silicon layer,
   implanting sulphur atoms is performed in at least one unmasked zone of the silicon layer,
   a step of removing the mask preceding the step of wet oxidising said silicon layer.

The method according to a second embodiment wherein the substrate comprising a silicon layer is a substrate of the silicon On Insulator SOI type, said method being implemented for making at least one local isolation zone such as an isolation trench for example, including the following steps of:
a step of masking at least one zone of the silicon layer,
implanting sulphur atoms is performed in at least one unmasked zone of the silicon layer intended to form the local isolation zone, so that the sulphur atoms are implanted under the oxide layer,
wet oxidising said silicon layer implanted,
removing the oxide with stopping on the silicon layer.

Another aspect of the invention is a device including an SOI substrate oxidised by the method of an embodiment of the invention and having at least one local isolation zone comprising sulphur.

According to an embodiment, the device according to the invention includes a transistor formed on the top silicon layer of the SOI substrate.

### BRIEF DESCRIPTION OF THE FIGURES

Further characteristics and benefits of the invention will become apparent from the description thereof given below, by way of indicating and in no way limiting purposes, with reference to the appended figures, in which:

FIG. 1 represents, in the form of a flow chart, the different steps of the method of the invention according to an embodiment,

FIG. 2, FIG. 3 and FIG. 4 represent the different steps of the method of [FIG. 1],

FIG. 5 represents a concentration profile of sulphur atoms implanted during implementation of the method of an embodiment of the invention,

FIG. 6 shows the oxide thickness obtained for samples made with different thicknesses of the sulphur-implanted layer after oxidation at different temperatures,

FIG. 7 represents, in the form of a flow chart, the different steps of the method of an embodiment of the invention,

FIG. 8, FIG. 9 and FIG. 10 represent the different steps of the method of [FIG. 7],

FIG. 11 shows the oxide thickness obtained for samples made with different thicknesses of the sulphur-implanted layer and an initial oxide thickness after oxidation at different temperatures,

FIG. 12 shows the oxide thickness obtained for samples made with the same thickness of sulphur-implanted layer at different sulphur concentrations after oxidation at 850° C. for different durations,

FIG. 13 shows the course of the oxide thickness formed as a function of time for different samples,

FIG. 14 shows the course of the oxidation rate for different samples,

FIG. 15 and FIG. 16 illustrate examples of the oxidation method according to an embodiment of the invention.

For greater clarity, identical or similar elements are identified by identical reference signs throughout the figures.

### DETAILED DESCRIPTION

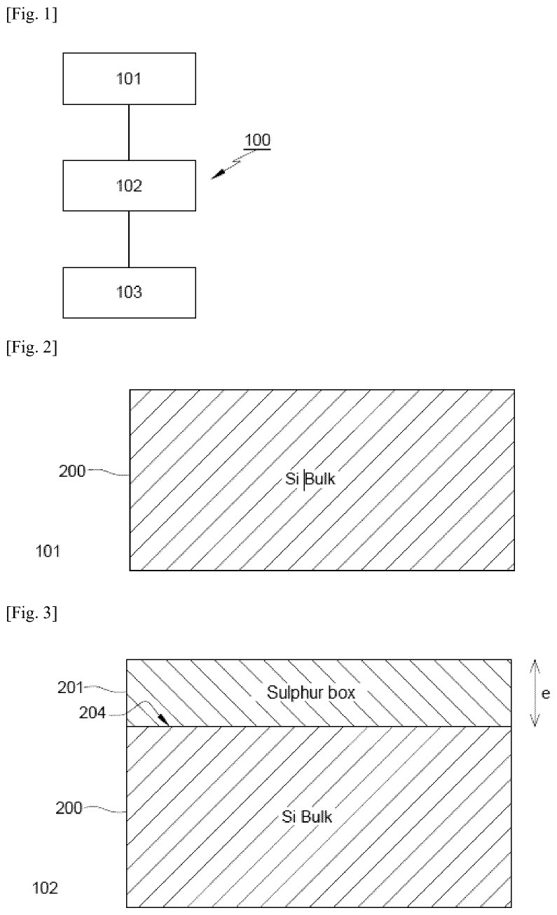

FIG. 1 represents a flow chart illustrating the different steps of the method 100 for oxidising a silicon layer according to one embodiment of the invention.

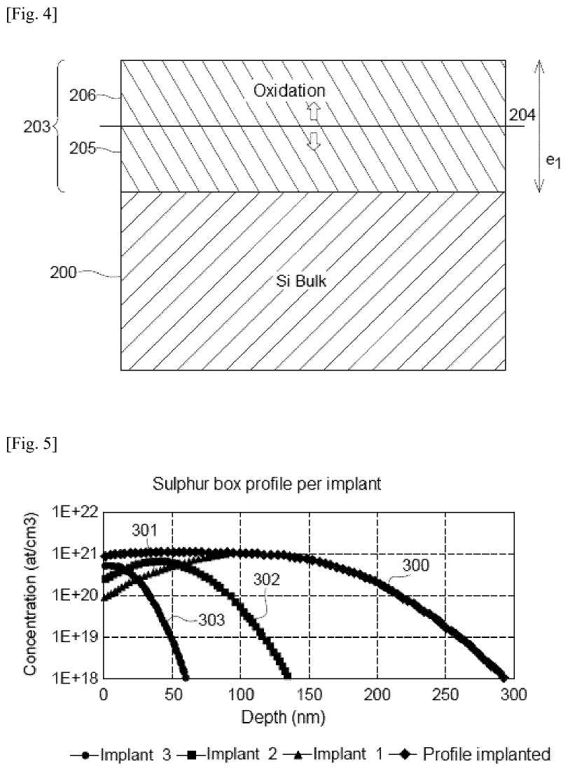

As shown in FIG. 2, the method 100 begins with a step 101 of providing a substrate 200 including a silicon layer. Herein, the substrate 200 is a bulk substrate entirely made of single crystal Si so that the Si layer and the substrate are one and the same. However, as will be seen later, aspects of the invention are not limited to the Si bulk substrate and the silicon layer may, for example, be a single crystal silicon layer belonging to a silicon On Insulator (SOI) substrate or a silicon layer deposited onto any stack of layers.

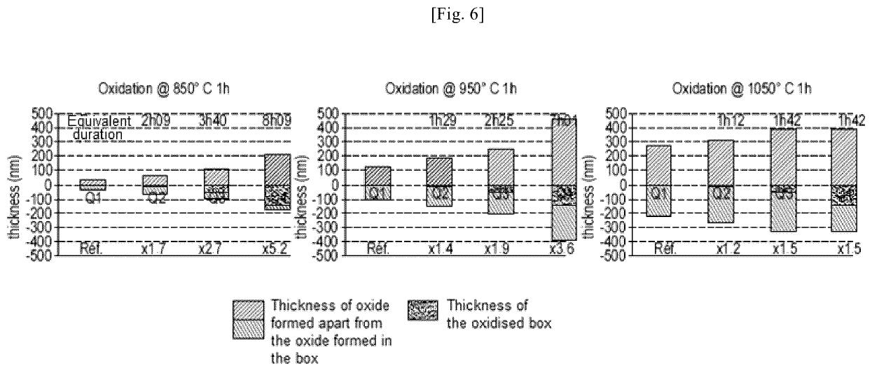

The method of an embodiment of the invention continues with a step 102 (FIG. 3) corresponding to making of a box 201 of sulphur atoms in the Si layer 200. In other words, at least one zone 201 of the Si layer is doped with sulphur atoms over a given thickness e measured perpendicularly to the plane of the Si layer. Making the sulphur box 201 in the silicon layer is achieved by at least one step of ion implanting sulphur atoms in the Si layer 200. According to the desired thickness e, it may be useful to perform several successive implantations of sulphur atoms in the Si layer 200 in order to achieve a homogeneous concentration of sulphur over the entire thickness e (also designated by the term depth). By way of illustration, FIG. 5 shows the concentration profile 300 of sulphur atoms (in at/cm³) implanted to achieve a homogeneous concentration of 10²¹ at/cm³ over a depth of 150 nm. Such a profile 300 is obtained by means of three successive implantations of sulphur ions in the Si layer:
A first implantation 301 with an accelerating voltage of 80 kV, a dose of 1.5·10¹⁶ cm⁻², a tilt angle of 0° and a twist angle of 0°,
A second implantation 302 with an acceleration voltage of 24 kV, a dose of 5·10¹⁵ cm⁻², a tilt angle of 7° and a twist angle of 27°,
A third implantation 303 with an acceleration voltage of 2.25 kV, a dose of 2.5·10¹⁵ cm⁻², a tilt angle of 7° and a twist angle of 27°.

As a reminder, the two implantation angles required to parameterise the ion beam relative to the crystal lattice can be defined. These angles are tilt T and twist R. Tilt T is the angle between the ion beam and the normal to the surface of the target substrate. Twist R is the angle between the incident beam and the axis of the substrate notch.

The method 100 continues with a step 103 (FIG. 4) of oxidising the silicon layer 200 vertically beneath the sulphur box 201 corresponding to a sulphur-doped silicon layer. According to an embodiment of the invention, the oxidation is a wet (i.e. in the presence of a water vapour atmosphere) thermal (at a temperature greater than or equal to 700° C.) oxidation. The silicon layer 200 and the box 201 react with the oxidising element to form an SiO2 layer 203 by consuming silicon. The Si/SiO2 interface will be situated below the initial surface 204 of the sulphur box 203 and penetrate the initial sulphur-undoped silicon layer. In a known manner, the oxide layer thickness fraction located below the initial surface 204 accounts for about 46% of the total oxide thickness and the oxide thickness fraction located above the initial surface 204 accounts for about 54% of the total oxide thickness.

According to a first experiment and in order to demonstrate benefits of the method of an embodiment of the invention, samples Q2, Q3 and Q4 have been made with different thicknesses e of the sulphur-implanted layer 201.

Sample Q1 will be considered in the following as a reference sample without sulphur implantation. Sample Q2 has an implantation thickness of 10 nm. Sample Q3 has an implantation thickness of 50 nm and sample Q4 has an implantation thickness of 150 nm. The sulphur concentration in samples Q2, Q3 and Q4 is equal to 10²¹ at/cm³.

Each of the samples Q1, Q2, Q3 and Q4 is then subjected to wet oxidation for 1 hour at three different temperatures, 850° C., 950° C. and 1050° C. respectively.

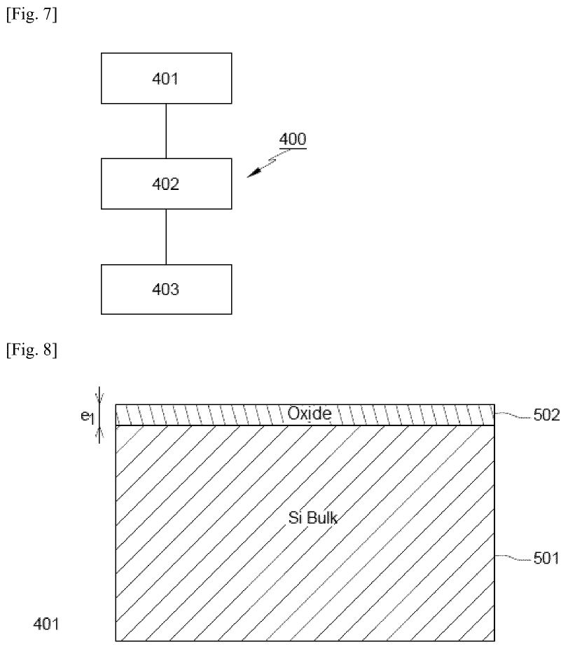

FIG. 6 shows the oxide thickness obtained for each of the samples after oxidation at each of the aforementioned temperatures. For each of the representations, the 0 nm reference corresponds to the initial surface of the sulphur box for samples Q2, Q3 and Q4 and to the initial surface of the silicon layer for the reference sample Q1 (i.e. without implantation). The oxidised zone is in each case broken down into two parts: the thickness of oxide formed in the sulphur box and the thickness of oxide formed above the top initial surface of the sulphur box (or above the top initial surface of the Si layer in the case of sample Q1) and below the bottom initial surface of the sulphur box (or below the bottom initial surface of the Si layer in the case of sample Q1). Below each thickness of samples Q2, Q3 and Q4 is represented a multiplier factor corresponding to the ratio of the oxide thickness of the given sample to the oxide thickness of the reference sample Q1.

Whatever the oxidation temperature, it is observed that the ratio increases as the thickness of the sulphur box increases, said ratio being systematically strictly greater than 1. Thus the presence of sulphur makes it possible, for a same oxidation time, to have a greater thickness of oxide than in the case of the reference sample. In addition, oxide growth is accelerated as the thickness of the box increases: by way of illustration, at 850° C., the ratio is 1.7 for a 10 nm box and rises to 5.2 for a 150 nm box. The method of an embodiment of the invention can therefore effectively modulate the thermal oxidation rate of silicon and achieve oxidation ratios well in excess of 2. As is well known, the oxidation rate increases with the temperature at which oxidation is performed. It will be further noted that the same results cannot be obtained using dry oxidation.

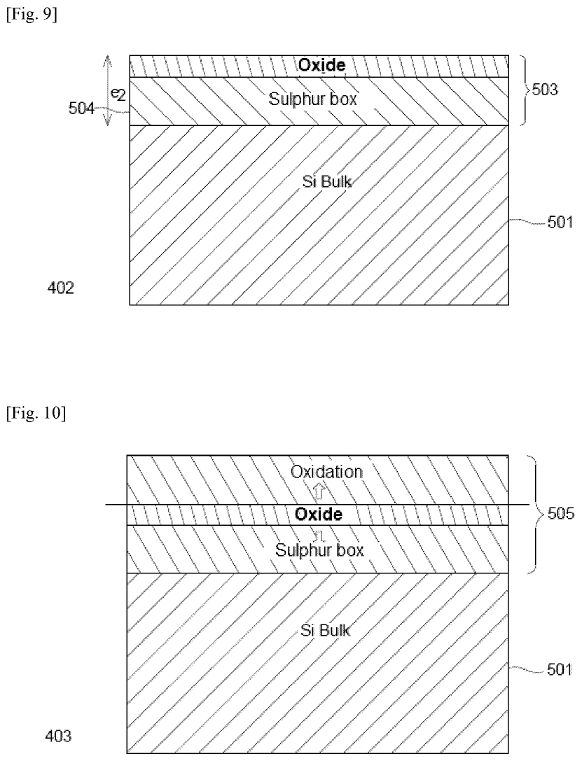

FIG. 7 represents a flow chart illustrating the different steps of the method 400 for oxidising a silicon layer according to a second embodiment of the invention.

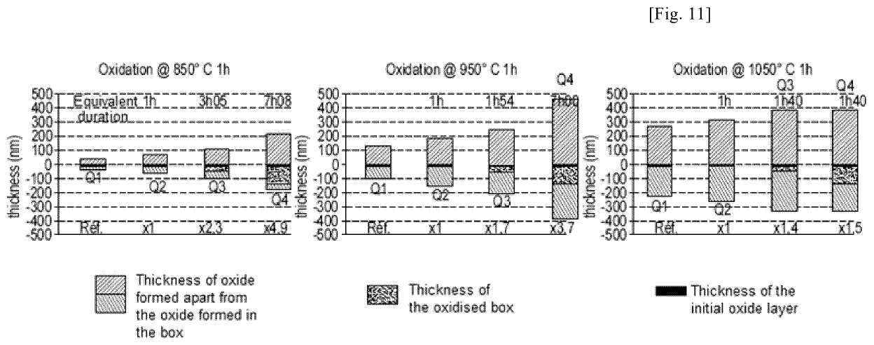

As shown in FIG. 8, the method 400 begins with a step 401 of providing a substrate 500 including a silicon layer 501 (herein in the form of a bulk substrate made entirely of single crystal Si) whose top surface is oxidised (presence of an oxide layer 502) to a thickness e1, herein equal to 20 nm.

The method 400 according to an embodiment of the invention continues with a step 402 (FIG. 9) corresponding to making a box 503 of sulphur atoms in the stack formed by the Si layer 501 and the oxide layer 502. It will be noted that in FIG. 9, the sulphur-implanted zone covers both the thickness e1 of oxide and part of the thickness of the Si layer (the importance of this characteristic will be seen in the following). In other words, at least one zone 504 of the Si layer non-oxidised is doped with sulphur atoms. The total thickness e2 of the sulphur box 503 is measured perpendicularly to the plane of the Si layer. As previously, making the sulphur box 503 is achieved by at least one step of ion implanting sulphur atoms into the Si layer 501 and the oxide layer 502 vertically above it. As discussed for the first embodiment, according to the thickness e2 sought, it may prove useful to make several successive implantations of sulphur atoms in the Si layer 501 in order to achieve a homogeneous concentration of sulphur over the entire thickness e2.

The method 400 continues with a step 403 (FIG. 10) of oxidising the silicon layer 501 vertically beneath the sulphur box 504 corresponding to a sulphur-doped silicon layer and the sulphur-implanted oxide layer. According to an embodiment of the invention, oxidation is a wet (i.e. in the presence of a water vapour atmosphere) thermal (at a temperature greater than or equal to 800° C.) oxidation. The silicon layer 501 and the box 504 react with the oxidising element to form an SiO2 layer 505 by consuming silicon.

According to a second experiment and in order to illustrate properties of this second embodiment, samples Q2, Q3 and Q4 have been made with different thicknesses e2 of the sulphur-implanted layer 503 (still with an initial oxide layer of thickness e1 equal to 20 nm).

Sample Q1 will be considered in the following as a reference sample without sulphur implantation but with an initial oxide layer 20 nm thick. Sample Q2 has an implantation thickness of 10 nm. Sample Q3 has an implantation thickness of 50 nm and sample Q4 has an implantation thickness of 150 nm. The sulphur concentration in samples Q2, Q3 and Q4 is equal to 10²¹ at/cm³.

Each of the samples Q1, Q2, Q3 and Q4 is then subjected to wet oxidation for 1 hour at three different temperatures, 850° C., 950° C. and 1050° C. respectively.

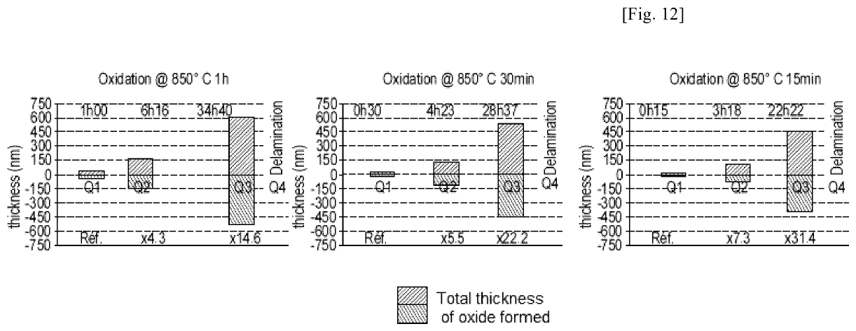

FIG. 11 shows the oxide thickness obtained for each of the samples after oxidation at each of the aforementioned temperatures. For each of the representations, the 0 nm reference corresponds to the initial surface of the initial oxide layer for samples Q1, Q2, Q3 and Q4. The aim of these experiments is to see whether acceleration of oxidation by virtue of sulphur occurs only in silicon or whether the same phenomenon is observed in the initial sulphur-implanted oxide layer.

The oxidised zone is in each case broken down into three parts: the thickness of oxide formed in the sulphur box, the initial oxide thickness and the thickness of oxide formed above the top surface of the initial oxide layer and below the bottom surface of the sulphur box (or below the bottom surface of the initial oxide layer in the case of sample Q1). Under each thickness of samples Q2, Q3 and Q4 is represented the multiplier factor corresponding to the ratio of the oxide thickness of the given sample to the oxide thickness of the reference sample Q1.

Whatever the oxidation temperature, it is observed that the ratio is equal to 1 when the sulphur box is formed exclusively in the initial oxide (i.e. the thickness of the sulphur box is equal to 10 nm, i.e. less than the initial oxide thickness of 20 nm). In other words, in the case where sulphur is implanted only in the initial oxide, no effect on the acceleration of oxidation is observed. It is therefore actually the presence of sulphur in the unoxidised silicon layer that causes the acceleration of oxidation. This observation is confirmed by the other ratios which are strictly greater than 1 when the thickness of the sulphur box increases so that the sulphur is present in silicon. By way of illustration, at 850° C., the ratio is 2.3 for a 50 nm box (50 nm being much greater than the initial oxide thickness of 20 nm) and rises to 4.9 for a 150 nm box (150 nm also being greater than the initial oxide thickness of 20 nm). The method of an embodiment of the invention therefore enables the thermal oxidation rate of silicon to be modulated effectively and oxidation ratios well in excess of 2 to be achieved when sulphur is implanted in silicon (the thickness of the box should therefore be strictly greater than the thickness of the initial oxide). As previously and in a known manner, it is observed that the thermal oxidation rate increases with the temperature at which oxidation is performed.

The inventors have additionally analysed the effect of the sulphur concentration in the implanted chamber on the method of an embodiment of the invention. Thus, in a third experiment and with reference to FIG. 3, samples Q2, Q3 and Q4 have been made with a same thickness of implanted layer 201 of 150 nm and different sulphur concentrations in this layer.

Sample Q1 will be considered in the following as a reference sample. Sample Q2 has a sulphur concentration equal to 5.10²⁰ at/cm³. Sample Q3 has a sulphur concentration equal to 2·10²¹ at/cm³. Sample Q4 has a sulphur concentration equal to 5·10²¹ at/cm³.

Each of the samples Q1, Q2, Q3 and Q4 is then subjected to wet oxidation at 850° C. for 1 h, 30 min and 15 min respectively.

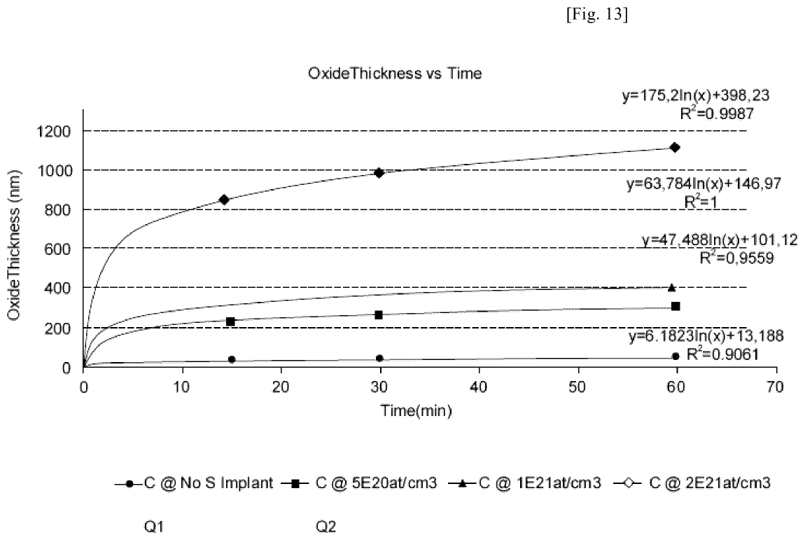

FIG. 12 shows the oxide thickness obtained for each of the samples after oxidation for each of the aforementioned oxidation durations. For each of the representations, the 0 nm reference corresponds to the initial surface of the sulphur box for samples Q2, Q3 and Q4 and to the initial surface of the silicon layer for the reference sample Q1 (i.e. without implantation).

Thus, it is observed in FIG. 12 that above a concentration, oxidation is less effective and delamination phenomenon occurs. Thus, in an embodiment, the sulphur concentration in the zone implanted is strictly lower than 5·10²¹ at/cm³ (the sulphur concentration for which delamination is observed in FIG. 12) and in an embodiment strictly lower than 3·10²¹ at/cm³. For all other concentrations, an oxidation ratio strictly greater than 1 and therefore an acceleration of oxidation related to the presence of sulphur are observed.

C(V) type electrical characterisations appear to show that the oxides obtained via sulphur implantation according to an embodiment of the invention have electrical properties similar to those of the oxides obtained without sulphur: in other words, oxides obtained via sulphur implantation according to an embodiment of the invention appear to exhibit no electrical degradation compared to the oxides obtained without sulphur.

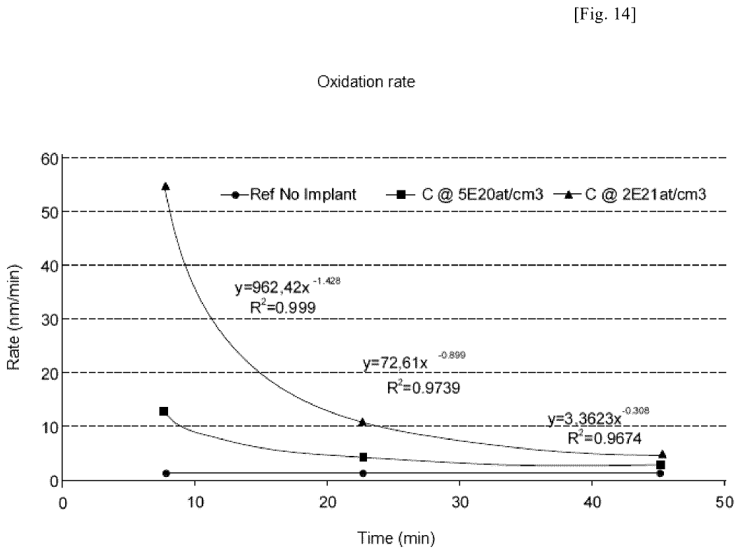

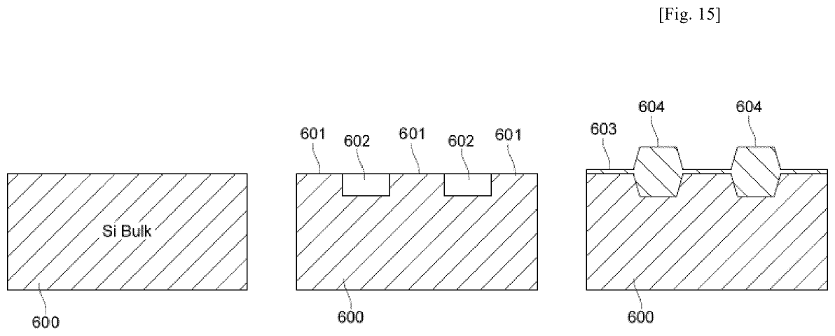

FIG. 13 shows the course of the thickness of oxide formed as a function of time for samples Q1, Q2 and Q3 as well as for an additional sample with a sulphur concentration equal to 1·10²¹ at/cm³. FIG. 14 shows the course of the oxidation rate for samples Q1, Q2 and Q3 of FIG. 12. Thus, an acceleration of oxidation during the first few minutes of oxide formation, a saturation of the oxidation rate can be observed from some depth. In other words, the benefit of sulphur doping relating to the increase in oxidation rate is particularly visible during the first few minutes of oxidation.

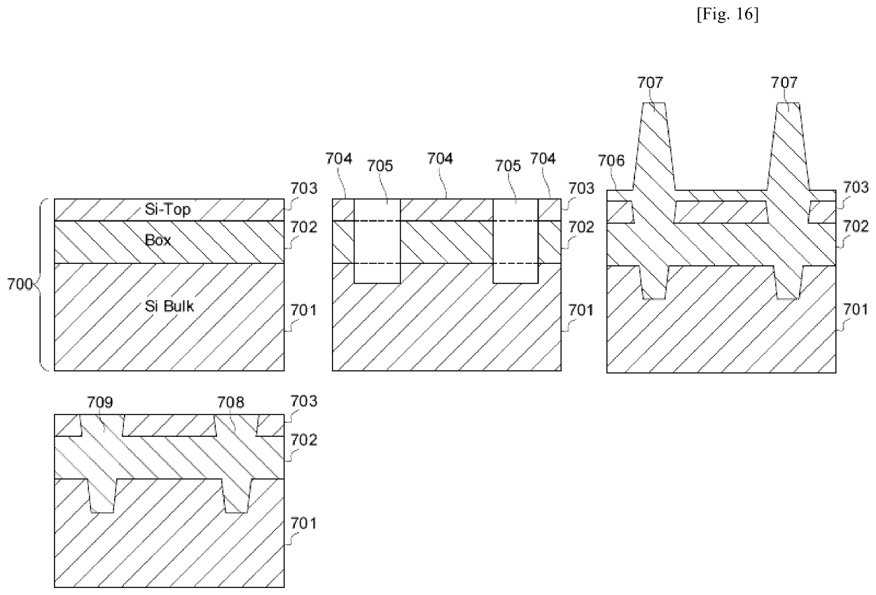

FIGS. 15 and 16 illustrate examples of application of the oxidation method of the invention.

FIG. 15 shows the use of the method of an embodiment of the invention within the scope of a LOCOS or “Local Oxidation of Silicon” technology. To this end, the starting point is a silicon substrate 600. In accordance with an embodiment of the invention, sulphur boxes 602 are thereby implanted (herein two sulphur boxes 602 are represented). The implantation is preceded by a masking step defining masked zones 601.

The masking operations are obtained by LOCOS lithography to make masks (for example of resin) to protect some regions of the substrate 600.

The implantation step is followed by a resin removal step, for example by stripping.

According to an embodiment of the invention, the sulphur-implanted silicon zones 602 and the non-implanted silicon zones 601 are then subjected to wet oxidation so as to obtain a silicon layer 603 oxidised with thicker oxidation zones 604 where the sulphur boxes 602 are located. The thicker oxidation zones 604 will especially provide isolation between components and are obtained by a reduced number of steps.

FIG. 16 shows the use of the method of an embodiment of the invention within the scope of a STI (Shallow Trench Isolation) technology.

To do this, the starting point is a silicon substrate 600 of the silicon On Insulator (SOI) type 700 including a layer of single crystal silicon 703 above a buried isolating layer 702 commonly designated “BOX” above a lower region 701 of silicon.

In accordance with the method of an embodiment of the invention, sulphur boxes 705 are then implanted (herein two sulphur boxes 705 are represented). As mentioned previously, for the method of an embodiment of the invention to be effective, it is desirable for the sulphur implantation not to be carried out solely in the oxide 702; this is why the sulphur implantation is herein made in the top Si layer 703, in the buried oxide layer 702 but also in the Si layer 701. Performing the implantation is preceded by a masking step defining masked zones 704.

The masking operations are obtained by STI lithography for making resin masks to define the non-implanted patterns (masked zones 704).

The implantation step is followed by a resin removal step, for example by stripping.

According to an embodiment of the invention, the sulphur-implanted silicon and oxide zones 705 and the non-implanted silicon and oxide zones 704 are then subjected to wet oxidation so as to obtain a layer 706 of oxidised silicon with thicker oxidation zones 707 (i.e. with greater upward and downward growth) where the sulphur boxes 705 are located.

The thick oxidised zones 707 are then subjected to Chemical Mechanical Polishing (CMP), with stopping at the top surface of the top Si layer 703 to remove excess oxidised material from the surface and obtain isolating zones 708 planarised. Wet cleaning can also be performed to remove residual material and prepare the surface for subsequent manufacturing processes. The zones 707 can especially serve as isolation trenches enabling, for example, a transistor made on the top Si layer 703 to be isolated from other transistors.

It will be noted that equivalent durations are represented in each of FIGS. 6, 11 and 12: they illustrate the necessary oxidation duration applicable to a reference sample to achieve the same oxidation thickness as for the sulphur-implanted sample under the same oxidation conditions.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements, components, compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects or embodiments of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in an embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. A method for oxidising a silicon layer comprising:
providing a substrate comprising a silicon layer;
implanting at least once sulphur atoms in at least one zone of the silicon layer;
wet oxidising said silicon layer implanted.

2. The method according to claim 1, wherein the implanting of sulphur atoms is performed so as to obtain a sulphur concentration in the zone implanted strictly lower than 5·10²¹ at/cm³.

3. The method according to claim 2, wherein the sulphur concentration in the zone implanted is strictly lower than 3·10²¹ at/cm³.

4. The method according to claim 1, wherein the wet oxidising is performed:
i. in the presence of water vapour, or
ii. under an atmosphere that includes both water vapour and dioxygen, or
iii. under an atmosphere including water vapour and hydrogen chloride gas.

5. The method according to claim 1, wherein the substrate comprising a silicon layer further includes an oxide layer on the silicon layer, implanting then being performed such that the sulphur atoms are implanted under the oxide layer.

6. The method according to claim 1, wherein the wet oxidising is performed at a temperature strictly greater than 700° C.

7. The method according to claim 1, wherein implanting sulphur atoms is performed over a thickness greater than or equal to 10 nm.

8. The method according to claim 1, comprising a plurality of implantation steps successively performed and having different implantation doses and/or acceleration voltages so as to obtain a uniform sulphur concentration over a given thickness.

9. The method according to claim 1, comprising:
a. masking at least one zone of the silicon layer,
b. implanting sulphur atoms is performed in at least one unmasked zone of the silicon layer,
c. emoving the mask preceding the wet oxidising of said silicon layer.

10. The method according to claim 1, wherein the substrate comprising a silicon layer is a substrate of the Silicon On Insulator SOI type, said method being implemented for making at least one local isolation zone including the following steps of:
a. masking at least one zone of the silicon layer,
b. implanting sulphur atoms is performed in at least one unmasked zone of the silicon layer intended to form the local isolation zone, so that the sulphur atoms are implanted under the oxide layer,
c. wet oxidising said silicon layer implanted,
d. removing the oxide with stopping on the silicon layer.

11. The method according to claim 1, wherein said at least one local isolation zone is an isolation trench.

12. A device including an SOI substrate oxidised by the method according to claim 10 and having at least one local isolation zone including sulphur.

13. The device according to claim 12, comprising a transistor formed on the top silicon layer of the SOI substrate.
